(19) United States
(12) Patent Application Publication
(10) Pub. No.: US 2012/0274194 A1
(43) Pub. Date: Nov. 1, 2012

(54) ENCLOSURE ASSEMBLY

(75) Inventor: GANG-QIANG QIN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/439,942

(22) Filed: Apr. 5, 2012

(30) Foreign Application Priority Data
Apr. 28, 2011 (CN) 201110107962.3

(51) Int. Cl. H05K 7/20; H05K 5/02; H05K 7/18; A47B 81/00

(52) U.S. Cl. 312/236

(57) ABSTRACT

An enclosure assembly includes an enclosure and a heat-resolution assembly. The enclosure includes a mounting pole and an installation pole connected to the mounting pole. The heat-resolution assembly includes a cushion, an installation plate and a mounting piece. The cushion is secured between the mounting pole and the installation pole. The installation plate is secured to the mounting pole and covers the cushion. The mounting piece covers and is secured to the installation plate. The cushion is secure between the enclosure and the installation plate, and the installation plate is secured between the cushion and the mounting piece.

### BACKGROUND

1. Technical Field

The present disclosure relates to enclosure assemblies, and particularly to an enclosure assembly of a container and a server.

2. Description of Related Art

In a data center container, a plurality of server racks may be provided for securing a plurality of servers. The plurality of servers operate under a temperature limitation. Thus, it is necessary to keep an internal temperature of the container under the temperature limitation. Therefore, an enclosure of the container with heat-resolution may be desired.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an enclosure assembly.

FIG. 2 is an isometric view of a partially assembled enclosure assembly of FIG. 1.

FIG. 3 is an assembled view of the enclosure assembly of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

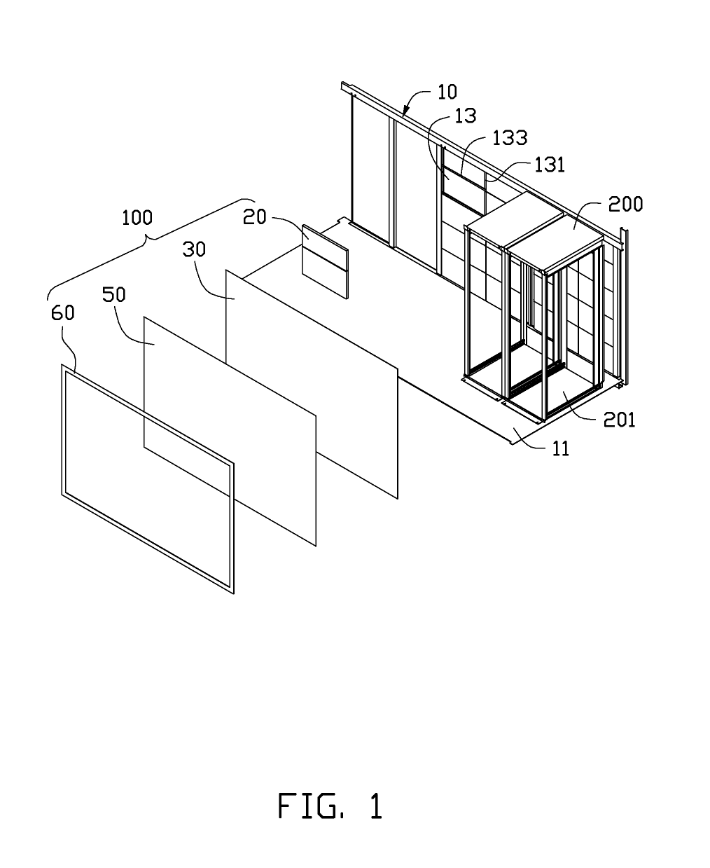

FIG. 1, is an enclosure assembly in accordance with an embodiment including an enclosure 10 (only a part shown in FIG. 1), and a plurality of racks 200 received in the enclosure 10.

The enclosure 10 includes a bottom plate 11 and a side plate 13. Each of the plurality of racks 200 is adapted to secure a plurality of servers and includes a bottom frame 201. The bottom frame 201 is secured to the bottom plate 11 with a plurality of locking members (not shown), such as screws. In one embodiment, the side plate 13 is substantially perpendicular to the bottom plate 11, and the enclosure 10 is a chassis of a data center container.

The side plate 13 includes a plurality of installation poles 131 and a plurality of mounting poles 133 secured to each adjacent two of the plurality of installation poles 131. In one embodiment, the plurality of the installation poles 131 are substantially parallel to each other and perpendicular to the bottom plate 11, and the plurality of mounting poles 133 are substantially parallel to the bottom plate 11. Each adjacent two of the plurality of mounting poles 133 and each adjacent two of the plurality of installation poles 131 defines a receiving space.

The enclosure assembly further includes a heat-resolution assembly 100.

The heat-resolution assembly 100 includes a plurality of cushions 20, an installation plate 30, a mounting piece 50, and a mounting frame 60. In one embodiment, the plurality of cushions 20, the installation plate 30, the mounting piece 50 and the mounting frame 60 are rectangular, and each of the plurality of cushions 20 is made of heat-resolution material, such as foam or rockwool. In one embodiment, the installation plate 30 is made of wood, the mounting piece 50 is an aluminum-plastic piece, and the mounting frame 60 is made of stainless steel. An area of the installation plate 30 is substantially equal to that of the mounting piece 50.

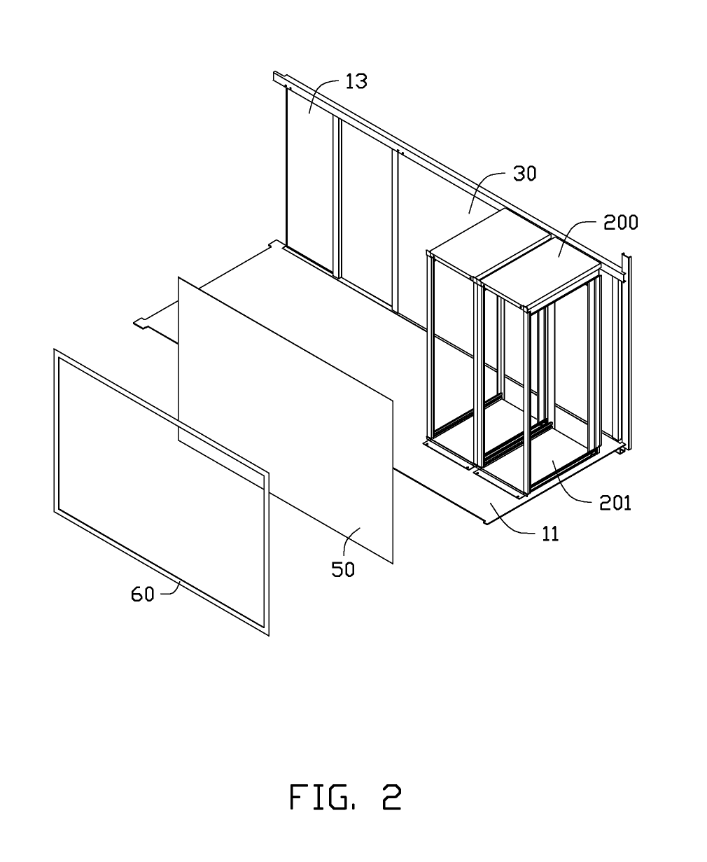

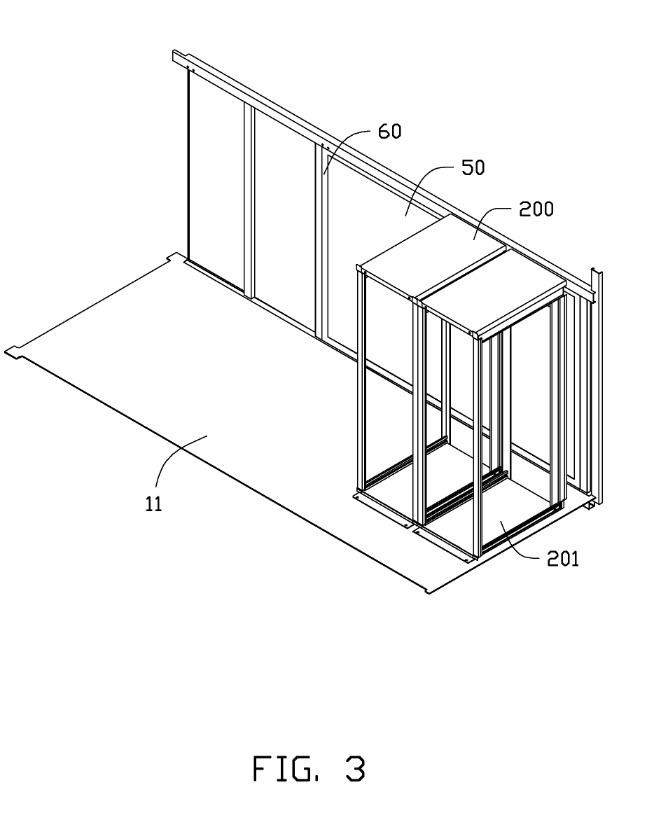

FIG. 2 and FIG. 3, show in assembly, each of the plurality of cushions 20 is received in the receiving space and abuts the plurality of installation poles 131 and the plurality of mounting poles 133. The installation plate 30 is secured to the plurality of mounting poles 133 with screws and covers the plurality of cushions 20. The plurality of cushions 20 are secured between the side plate 13 and the installation plate 30. The mounting piece 50 is secured to and covers the installation plate 30. The installation plate 30 is secured between the plurality of cushions 20 and the mounting piece 50. The mounting frame 60 is secured to edges of the mounting piece 50, to cover a gap between the mounting piece 50 and the side plate 13.

In use, an internal temperature of the enclosure 10 is stable because of the heat-resolution assembly 100. The heat-resolution assembly 100 prevents the inner temperature from affecting by an outer temperature of the enclosure 10 and provides a normal working environment for the servers.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An enclosure assembly comprising:
an enclosure comprising a mounting pole, and an installation pole connected to the mounting pole;
a heat-resolution assembly, and the heat-resolution assembly comprising:
a cushion secured between the mounting pole and the installation pole;
an installation plate secured to the mounting pole and covering the cushion; and
a mounting piece covering and secured to the installation plate;
wherein the cushion is secured between the enclosure and the installation plate, and the installation plate is secured between the cushion and the mounting piece.

2. The enclosure assembly of claim 1, wherein the cushion is made of heat-resolution material.

3. The enclosure assembly of claim 1, wherein the cushion is made of foam.

4. The enclosure assembly of claim 1, wherein the cushion is made of rockwool.

5. The enclosure assembly of claim 1, wherein the installation plate is made of wood.

6. The enclosure assembly of claim 1, wherein the mounting piece is an aluminum-plastic piece.

7. The enclosure assembly of claim 1, wherein the heat-resolution assembly further comprises a mounting frame, the mounting frame is secured to edges of the mounting piece and covers a gap between the mounting piece and the enclosure.

8. The enclosure assembly of claim 1, wherein the mounting pole is substantially perpendicular to the installation pole.

9. The enclosure assembly of claim 1, wherein the enclosure is a chassis of a container data center.

10. The enclosure assembly of claim 1, wherein the enclosure is adapted to secure a plurality of server racks and comprises a bottom plate, and the plurality of server racks is locked on the bottom plate.

11. An enclosure assembly comprising:
an enclosure comprising two mounting poles opposite to each other, and two installation poles opposite to each other, each of the two installation poles is connected to each of the two mounting poles; and
a heat-resolution assembly, and the heat-resolution assembly comprising:
a plurality of cushions secured between the two mounting poles and the two installation poles;
an installation plate secured to one of the two mounting poles and covering the plurality of cushions;
a mounting piece covering and secured to the installation plate; and
a mounting frame secured to edges of the mounting piece and covering a gap between the mounting piece and the enclosure;
wherein the plurality of cushions are secure between the enclosure and the installation plate, and the installation plate is secured between the plurality of cushions and the mounting piece.

12. The enclosure assembly of claim 11, wherein each of the plurality of cushions is made of heat-resolution material.

13. The enclosure assembly of claim 11, wherein each of the plurality of cushions is made of foam.

14. The enclosure assembly of claim 11, wherein each of the plurality of cushions is made of rockwool.

15. The enclosure assembly of claim 11, wherein the installation plate is made of wood.

16. The enclosure assembly of claim 11, wherein the mounting piece is an aluminum-plastic piece.

17. The enclosure assembly of claim 11, wherein the two mounting poles are substantially perpendicular to the two installation poles.

18. The enclosure assembly of claim 11, wherein the enclosure is a chassis of a container data center.

19. The enclosure assembly of claim 11, wherein the enclosure is adapted to secure a plurality of server racks and comprises a bottom plate, and the plurality of server racks is locked in the bottom plate.
